(19) United States
(12) Patent Application Publication
(10) Pub. No.: US 2023/0356505 A1
(43) Pub. Date: Nov. 9, 2023

(54) LAMINATE WITH INTEGRAL FORCE SENSOR AND RELATED METHODS

(71) Applicant: Corning Incorporated, Corning, NY (US)

(72) Inventors: Santanu Basu, Palo Alto, CA (US); Peter Steven Cole, Corning, NY (US); Sean Matthew Garner, Elmira, NY (US)

(21) Appl. No.: 17/777,454

(22) PCT Filed: Nov. 20, 2020
(86) PCT No.: PCT/US2020/061427

§ 371 Date: May 17, 2022

Related U.S. Application Data
(60) Provisional application No. 62/939,246, filed on Nov. 22, 2019.

(51) Int. Cl. B32B 17/10; B32B 17/06; G01L 5/00

(52) U.S. Cl. CPC B32B 17/10064; B32B 17/067; B32B 17/061; B32B 17/10376; G01L 5/0061; B32B 2307/7376; B32B 2305/34

(57) ABSTRACT

Various embodiments for a laminate glass article having an integrated switch therein and related methods are provided. The laminated glass article a force sensor configured within one or more layers of the laminate with sufficient spacer incorporation to provide a force sensing switch. Related methods are also provided.

### CROSS REFERENCE TO RELATED APPLICATIONS

This application claims the benefit of priority under 35 U.S.C. § 119 of U.S. Provisional Application No. 62/939,246 filed Nov. 22, 2019, the content of which is incorporated herein by reference in its entirety.

### FIELD OF THE INVENTION

Broadly, the present disclosure is directed towards embodiments having integrated electronics fabricated directly onto or into a glass laminate. More specifically, the present disclosure is directed towards various embodiments of laminates having force sensors configured with actuating spacers and/or adjacent spacers, such that the laminate, as manufactured and/or as-installed is configured in a no strain initial position, such that the dynamic range of the force sensor is maintained within the laminate.

### BACKGROUND

Glass surfaces are widely used for touch sensing. Force sensing has a few advantages over touch sensing: (1) it is much less affected (a) by surface contamination and also (b) presence of additional materials (for example, grease) on the surface and (2) force sensing is more immune than touch sensing to what is touching the surface: for example touch sensing depends greatly on whether the user is using bare fingers or fingers with gloves, whereas force sensing should work with both of these cases. For architectural use over tens of years, force sensing is expected to be better suited than touch sensing. Incorporating force sensors into architectural products is challenging.

### SUMMARY

Broadly, the present disclosure is directed towards embodiments having electronic or optoelectronic functionality incorporated into a laminate having glass. More specifically, the present disclosure is directed towards various embodiments of laminates which have the capability to control operation of electronic devices by application of force (pressure) on at least one surface of the laminate. This is accomplished by incorporating force sensors in the construction of the laminate and directing the signal from the sensors to at least one device for control of at least one device which may be of electronic, electrical or optoelectronic nature. In addition, the force sensor and the accessories may be incorporated in a manner that does not affect the appearance of at least one surface of the laminate so that the laminate may retain aesthetic appeal for architectural, automotive and other uses. Also the construction of the laminate is configured such that it is easy for the users to control operation of various devices by pressing the laminate surface with finger.

Generally, the present disclosure is directed towards embodiments of a laminate with an embedded/integrated electronic or optoelectronic device. These devices include lighting, temperature sensor, display, touch sensor, haptics, antenna, force sensor. The device retains functionality and sensitivity in its embedded state. In the case of a force sensor, the sensitivity is defined by change in resistance or capacitance, or generated electrical charge as a function of applied force (sensor actuation) by pressing on the outer surface (thin glass) of the laminate. The laminate configuration set forth herein is configured such that the sensor sensitivity in the laminated state is the same as in the unlaminated state. For brevity, we call this state of the sensor “normal state” throughout this document, in which the laminated sensor behaves similar to an unlaminated sensor. A loss in the sensor sensitivity over the range of applied force is minimized by design. The design is optimized to provide a positive user experience which results when the user uses neither excessive nor too light finger pressure on glass laminates and the user uses same amount of pressure on different glass laminates at various places.

In some embodiments, the glass laminate is configured with an embedded/integrated force sensor that retains sensitivity in its embedded state, including resistance, capacitance or generated electrical charge is a function of applied force (sensor actuation) by pressing on the outer surface (thin glass) of the laminate. The laminate configuration set forth herein is configured without strain on the sensor (e.g. as-installed) and such that any strain applied to the laminate (e.g. via an actuation) is thereby transferred to the force sensor (e.g. without undue or excessive deformation of the laminate or its respective layers).

It is difficult to configure force (pressure) sensors within a glass laminate because of three reasons (1) the force sensor may become prestressed during the lamination process reducing the range of signal a user is able to generate from the laminate, (2) the required pressure on the laminate surface may be excessive to generate a signal from the force sensor embedded inside the laminate which again may reduce the range of signal a user is able to generate from the laminate, and (3) part to part variability in terms of different amount of signal being generated by applying the same force (pressure) on different laminates or on the same laminate at different sensor locations. With conventional force sensors based on the resistance effect, resistance vs. applied force is a very sensitive function. With glass laminates, another concern is that if the user needs to apply excessive force on the glass in the laminate to operate devices, it may result in surface damage to the glass laminate (e.g. glass breakage).

In one aspect, a glass laminate is provided, comprising: a top stack, the top stack configured from a glass layer and a backer substrate, wherein the glass layer is adhered to the backer substrate via an adhesive; a bottom stack, the bottom stack configured from a body substrate and body-backer substrate (e.g. steel), wherein the body-backer substrate is adhered onto the body substrate via an adhesive; wherein the top stack is configured to the bottom stack with an adhesive positioned therebetween; and a force sensor integrated into at least one of: the top stack and the bottom stack, wherein the force sensor is configured to electrically communicate with a device or system; wherein the glass laminate is configured to actuate a force sensor with a pressure event on the glass layer.

In some embodiments, a plurality of spacers are configured between the glass layer and the backer substrate, wherein the spacers are configured such that the at least one force sensor is in a zero resistance mode (e.g. no residual strain in a static, non-actuating configuration).

In some embodiments, the spacer according is an actuating spacer.

In some embodiments, the spacer according is an adjacent spacer (e.g. secondary spacer).

In some embodiments, a plurality of spacers are configured between the glass layer and the backer substrate, wherein the spacers are configured such that the at least one force sensor is in a “normal state”).

In some embodiments, the spacer is a sensor-retaining spacer which has a cutout (cavity) for the sensor.

In some embodiments, the spacer is a gap-filling spacer which fills the gap between the sensor and an adjacent layer in the laminate.

In some embodiments, the glass backing substrate is a thin glass. In some embodiments, the glass backing substrate is a thin flexible glass.

In some embodiments, the glass backing substrate has a thickness of not greater than 300 microns.

In some embodiments, layers of the laminate are adhered together with adhesive selected from the group consisting of: optically clear adhesive, pressure sensitive adhesive, and transparent tape.

In some embodiments, the body substrate comprises: MDF or HPL.

In some embodiments, the body backer substrate comprises a metal sheet (e.g. steel).

In some embodiments, the force sensor is configured with a plurality of spacer members, wherein the spacer members are positioned: (1) between the upper surface of the force sensor and the lower surface of the adjacent layer; (2) between two adjacent, spaced layers of the laminate and an edge of the sensor; and combinations thereof.

In some embodiments, the spacer includes at least one adjacent spacer and at least one actuating spacer.

In some embodiments, the adjacent spacer is configured with a sensor hole, sufficiently sized such the force sensor and electrical wiring are retained therein.

In some embodiments, the force sensor is configured with electrical wiring, wherein via the electrical wiring, an actuation signal is communicated to a location external to the glass laminate.

In some embodiments, the electrical wiring is configured to communicate an actuation signal from the force sensor in the laminate to a device or system, external to the laminate.

In some embodiments, the electrical wiring is configured to communicate an actuation signal from the force sensor in the laminate to a device or system, positioned on an external surface of the laminate or an adjacent position to the laminate.

In some embodiments, the electrical wiring is directed from the force sensor to exit the laminate via the spacer hole.

In some embodiments, the force sensor is housed in the backer-substrate in a substrate sensor hole.

In this embodiment, when the force sensor is thicker than the backer substrate, a combination of adjacent spacers and actuating spacers are utilized between the glass layer and the backing-substrate layer.

In this embodiment, when the force sensor is thinner than the backer substrate, an actuating spacer is utilized between the glass layer and the force sensor.

In some embodiments, the glass layer includes an inorganic glass.

In some embodiments, the glass layer is an alkaline earth boro-aluminosilicate glass.

In some embodiments, the force sensor is based on: resistance change, capacitance change, or piezoelectric effect.

In some embodiments, the force sensor is a polymeric force sensor (e.g. a piezoelectric polymer, polyvinylidene fluoride).

In some embodiments, the laminate is an architectural product.

In some embodiments, the laminate is an automotive product.

In one embodiment, a glass laminate is provided, comprising: a glass layer (e.g. thin glass layer, less than 300 microns); and a glass-backing substrate (e.g. metal, steel, MDF, HPL); at least one force sensor (e.g. positioned between the thin glass and a glass-backing substrate); and a plurality of spacers configured between the thin glass layer and the glass backing layer, wherein the spacers are configured such that the at least one force sensor is in a zero resistance mode when not under a pressure event (e.g. no residual strain in an as-assembled or static configuration).

In some embodiments, the spacer includes at least one adjacent spacer and at least one actuating spacer.

In some embodiments, the adjacent spacer is configured with a through hole, sufficiently sized such the force sensor and electrical wiring are retained therein.

In some embodiments, the force sensor is configured with electrical wiring to communicate the actuation signal to a location external to the glass laminate.

In some embodiments, the electrical wiring is directed from the force sensor to exit the laminate via the spacer hole.

In some embodiments, the force sensor is housed in the backer-substrate in a substrate sensor hole.

In this embodiment, when the force sensor is thicker than the backer substrate, a combination of adjacent spacers and actuating spacers are utilized between the glass layer and the backing-substrate layer.

In this embodiment, when the force sensor is thinner than the backer substrate, an actuating spacer is utilized between the glass layer and the force sensor.

In some embodiments, the spacer according is an actuating spacer.

In some embodiments, the spacer according is an adjacent spacer.

In some embodiments, the glass layer includes an inorganic glass.

In some embodiments, the glass layer is an alkaline earth boro-aluminosilicate glass.

In some embodiments, the force sensor is based on: resistance change, capacitance change, or piezoelectric effect.

In some embodiments, the force sensor is a polymeric force sensor (e.g. a piezoelectric polymer, polyvinylidene fluoride).

In some embodiments, the laminate is an architectural product.

In some embodiments, the laminate is an automotive product.

In another aspect, a method is provided, comprising: actuating a force sensor embedded in or on a glass laminate; generating an electrical signal in response to the actuating step; and controlling an electronic device or system with the electrical signal.

In some embodiments, the controlling comprises turning on, turning off, or adjusting the electronic device or system.

Additional features and advantages will be set forth in the detailed description which follows and will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary and are intended to provide an overview or framework to understanding the nature and character of the disclosure as it is claimed.

The accompanying drawings are included to provide a further understanding of principles of the disclosure, and are incorporated in, and constitute a part of, this specification. The drawings illustrate one or more embodiment(s) and, together with the description, serve to explain, by way of example, principles and operation of the disclosure. It is to be understood that various features of the disclosure disclosed in this specification and in the drawings can be used in any and all combinations. By way of non-limiting examples, the various features of the disclosure may be combined with one another according to the following aspects.

### BRIEF DESCRIPTION OF THE DRAWINGS

These and other features, aspects and advantages of the present disclosure are better understood when the following detailed description of the disclosure is read with reference to the accompanying drawings, in which:

FIG. 1 depicts embodiments of a laminate configuration in accordance with various embodiments of the present disclosure. The top stack and bottom stack are shown individually at the left, and their respective components (in non-limiting example form) are provided in the glass laminate layers depicted on the right. To the right of the glass laminate layers, there are 4 arrows shown, labeled A, B, C, and D, which are four non-limiting examples (embodiments) of force sensor placement, in accordance with the present disclosure.

FIG. 2A-2D depict various non-limiting examples (embodiments) of force sensor position, as indicated in FIG. 1, with a specific laminate configuration, in accordance with one or more embodiments of the present disclosure.

FIG. 3A depicts an embodiment of a laminate with force sensor configured to communicate with a control system, which actuates response in a device or system, in accordance with one or more embodiments of the present disclosure.

FIG. 3B depicts an embodiment of a laminate with force sensor configured to communicate (actuate or adjust) a device or system, in accordance with one or more embodiments of the present disclosure.

FIG. 4A depicts an embodiment of a channel configured in the laminate (e.g. sufficiently sized to retain electrical wiring and direct it along a portion (external edge) of the laminate, in accordance with one or more embodiments of the present disclosure.

FIG. 4B depicts an embodiment of a hole configured in the laminate (e.g. sufficiently sized to retain electrical wiring and direct it from inside the laminate to outside the laminate in accordance with one or more embodiments of the present disclosure.

FIG. 4C depicts an embodiment of a sensor hole configured in a substrate of a laminate (e.g. substrate body) with a force sensor positioned therein, in accordance with one or more embodiments of the present disclosure.

FIG. 5A depicts a schematic of Build 1 in the examples section, where the downward arrow indicates an actuating event (e.g. force or pressure applied to the top stack), in accordance with the present disclosure.

FIG. 5B depicts the Resistance (ohms) measured over Force applied (g), which shows the resistance at zero applied force vs. at maximum applied force for Build 1, meaning an overall reduced dynamic range for Build 1 of the examples, in accordance with the present disclosure.

FIG. 6A depicts a schematic of Build 2 in the examples section, where the downward arrow indicates an actuating event (e.g. force or pressure applied to the top stack) on the laminate (and thus, force sensor), in accordance with the present disclosure.

FIG. 6B depicts the Resistance (ohms) measured over Force applied (g), which shows the resistance at zero applied force vs. at maximum applied force for Build 2, meaning an overall reduced dynamic range for Build 2 of the examples, in accordance with the present disclosure.

FIG. 7A depicts a schematic of Build 3 in the examples section, where the downward arrow indicates an actuating event (e.g. force or pressure applied to the top stack) on the laminate (and thus, force sensor), in accordance with the present disclosure.

FIG. 7B depicts the Resistance (ohms) measured over Force applied (g), which shows the resistance at zero applied force vs. at maximum applied force for Build 3, meaning an overall reduced dynamic range for Build 3 of the examples, in accordance with the present disclosure.

FIG. 8A depicts a schematic of Build 4 in the examples section, where the downward arrow indicates an actuating event (e.g. force or pressure applied to the top stack) on the laminate (and thus, force sensor), in accordance with the present disclosure.

FIG. 8B depicts the Resistance (ohms) measured over Force applied (g), which shows the resistance at zero applied force vs. at maximum applied force for Build 4, meaning an overall wide dynamic range for Build 4 of the examples, in accordance with the present disclosure.

FIG. 9A depicts a schematic of Build 5 in the examples section, where the downward arrow indicates an actuating event (e.g. force or pressure applied to the top stack) on the laminate (and thus, force sensor), in accordance with the present disclosure.

FIG. 9B depicts the Resistance (ohms) measured over Force applied (g), which shows the resistance at zero applied force vs. at maximum applied force for Build 5, meaning an overall wide dynamic range for Build 5 of the examples, in accordance with the present disclosure.

FIG. 10 depicts a method of using an embodiment of a laminate having an onboard (e.g. configured onto or into) a laminate in accordance with the present disclosure.

### DETAILED DESCRIPTION OF THE DRAWINGS

In the following detailed description, for purposes of explanation and not limitation, example embodiments disclosing specific details are set forth to provide a thorough understanding of various principles of the present disclosure. However, it will be apparent to one having ordinary skill in the art, having had the benefit of the present disclosure, that the present disclosure may be practiced in other embodiments that depart from the specific details disclosed herein. Moreover, descriptions of well-known devices, methods and materials may be omitted so as not to obscure the description of various principles of the present disclosure. Finally, wherever applicable, like reference numerals refer to like elements.

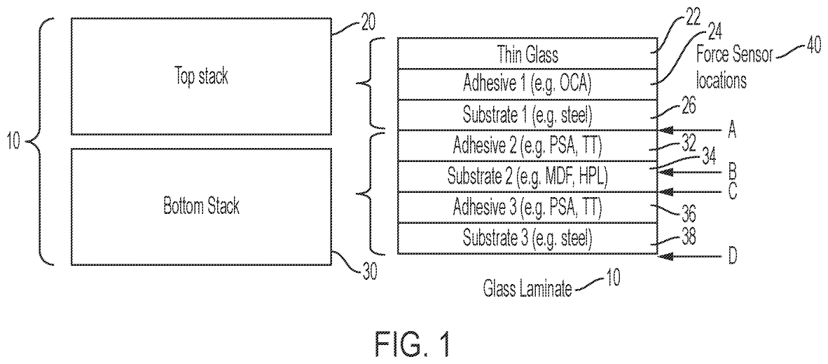

FIG. 1 depicts embodiments of a glass laminate 10 configuration in two views—generic top stack 20 vs. bottom stack 30 configuration on the left and on the right side: a more detailed schematic view of the various layers (including example materials) in each of the top stack 20 and bottom stacks 30 of the glass laminate 10. Also, with respect to the more detailed glass laminate 10 schematic view, there are four arrows indicating four non-limiting examples of positions within the glass laminate 10 where a force sensor 40 may be configured and/or located. The 4 arrows are denoted as A; B; C; and D.

Referring to FIG. 1, the top stack 20 of the glass laminate includes: a glass substrate (e.g. thin glass) 22 as the upper surface, followed by an adhesive layer 24 which adheres the thin glass 22 onto a substrate 26 (e.g. depicted as substrate 1, a glass backer substrate). The bottom stack 30 includes a substrate 34 adhered onto another substrate 38 (e.g. backer substrate, depicted as substrate 3) via an adhesive layer 36 (depicted as adhesive 3).

An adhesive 32 is configured between the top stack 20 and bottom stack 30 to adhere the two together, is adhered to the top stack 20 via an adhesive 32 (e.g. depicted as adhesive 2). While the adhesive 32 is depicted as in the bottom stack 30, it is also noted that the adhesive can be optionally configured in the top stack 20.

In force sensor 40 location A, the force sensor(s) 40 are positioned between the top stack 20 (beneath lower most layer of top stack) and the bottom stack 30 (above the upper most layer of top stack). In force sensor 40 location B, the force sensor(s) 40 are positioned within the substrate body 34 of the bottom stack 30 (e.g. substrate 2), via sensor hole(s)/laminate layer hole(s) 54 (or cut-outs) in the substrate body 34. In force sensor 40 location C, the force sensor(s) 40 are positioned between layers of the bottom stack 30, specifically, between substrate 2 34 (e.g. the substrate body), and substrate 3 38 (e.g. the substrate body backer). In force sensor 40 location D, the force sensor(s) 40 are positioned beneath the bottom stack 30.

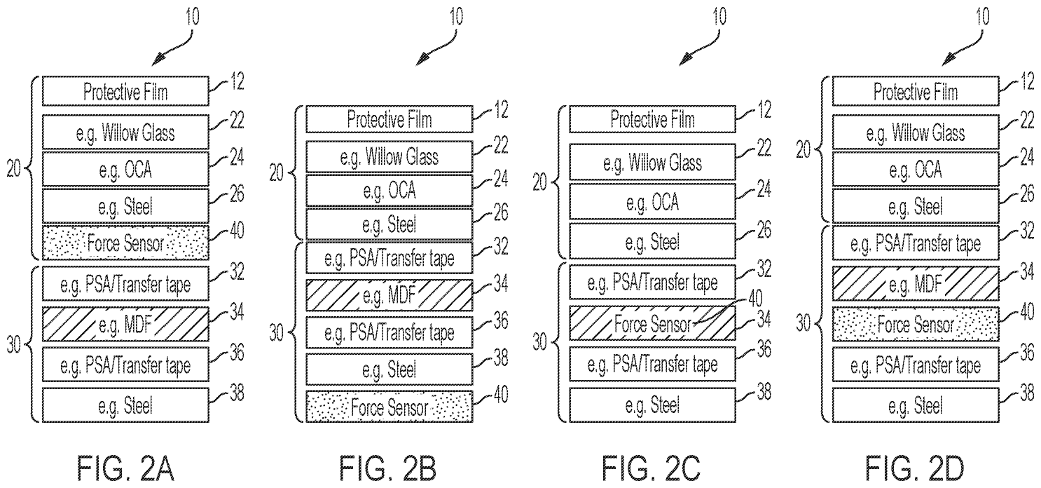

FIG. 2A-2D depict various non-limiting examples (embodiments) of force sensor position, as indicated in FIG. 1, with a specific glass laminate 10 configuration.

Additionally, FIGS. 2A through 2D depict a protective film 12 placed over the top (outer) surface of the glass laminate 22. FIG. 2A illustrates the force sensor 40 configured at the bottom of the top stack 20, between the top stack 20 and bottom stack 30. FIG. 2B illustrates the force sensor 40 positioned at the bottom of the bottom stack 30, below backer substrate 38, here shown as steel. FIG. 2C illustrates force sensor 40 positioned within the body of the substrate 34. FIG. 2D illustrates force sensor 40 positioned in the bottoms stack 20, beneath the substrate body 34/substrate 2.

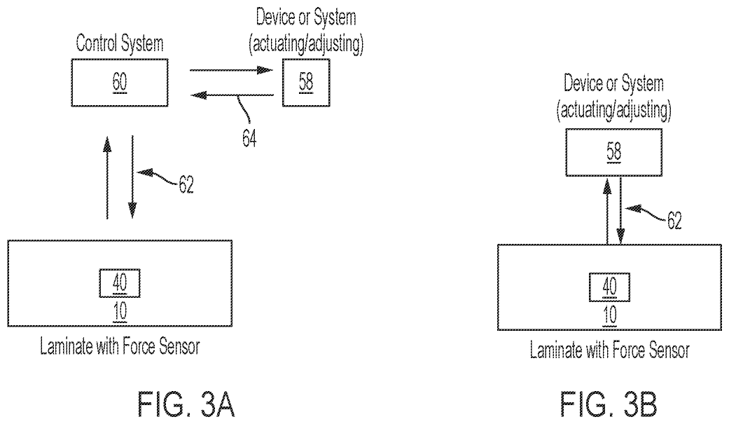

FIG. 3A depicts an embodiment of a glass laminate 10 with force sensor 40 configured to communicate with a control system 60 (via an electrical signal 62), which actuates response in a device or system 58 via control signal 64. The signal 64 from the control system 60 may generate a response to the device or system 58 to turn off the device or system, turn on the device or system, increase an adjustable and measurable attribute of the device or system, or decrease an adjustable and measurable attribute of the device or system.

FIG. 3B depicts an embodiment of a glass laminate 10 with force sensor 40 configured to communicate (actuate or adjust) a device or system 58 via a signal 62. The signal 62 from the glass laminate 10 with force sensor 40 may generate a response to the device or system 58 to turn off the device or system, turn on the device or system, increase an adjustable and measurable attribute of the device or system, or decrease an adjustable and measurable attribute of the device or system.

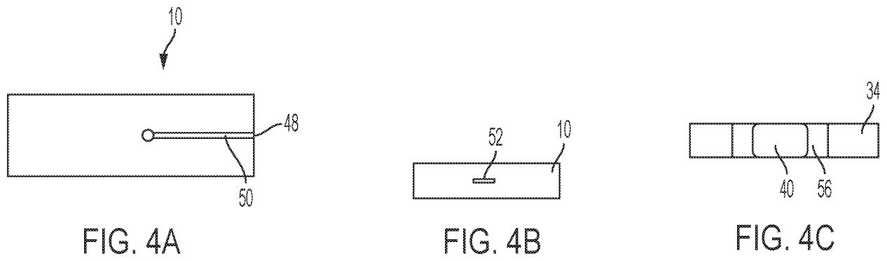

FIG. 4A depicts an embodiment of a channel 50 configured in the laminate 10 (e.g. sufficiently sized to retain electrical wiring and direct it along a portion (external edge) of the laminate 10 to the electrical connection 48.

FIG. 4B depicts an embodiment of a hole 52 configured in the laminate 10 (e.g. sufficiently sized to retain electrical wiring and direct it from inside the laminate 10 to outside the laminate 10, such that the signal 62 from actuation of the force sensor 40 can be directed to control a device or system 58, as set out herein.

FIG. 4C depicts an embodiment of a sensor hole 56 configured in a substrate 34 of a laminate 10 (e.g. substrate body) with a force sensor 40 positioned therein.

Referring to FIGS. 4A through 4C, in some embodiments, the channel is configured in laminate in a position to enable electrical wiring to extend from the sensor through the laminate, to an outer edge/outlet point from the laminate. In some embodiments, the hole is the exit point of the electrical wiring from in the laminate body. In some embodiments, the laminate layer hole is a via or opening positioned within the existing substrate layer such that the sensor is able to be positioned within the cross-sectional thickness of the substrate layer. In this embodiment, the sensor cross-sectional thickness does not add unnecessarily the overall laminate thickness; rather, the sensor is recessed within a substrate cross-sectional thickness. In some embodiments, the sensor hole is configured for the sensor positioned in an adjacent spacer layer. In some embodiments, the device or system is the component or member being controlled via actuation of the sensor/switch.

### Example: Description of a Laminate Device Having Force Sensor

A typical glass laminate as shown in the Figures may be thought of as a laminate of two laminates: a top stack and a bottom stack as shown in the Figures. The top stack is glass layer (e.g. a thin piece of glass such as 0.2 mm thick Willow® glass) which is laminated (e.g. via an adhesive like optically clear adhesive, OCA) on backer substrate (e.g. solid backing such as 0.45 mm steel or 0.40 mm thick high pressure laminate) to give the top stack structural rigidity and strength. The top stack is self-contained and can be handled by itself.

The bottom stack is made of a laminate which typically does not contain glass, and it may be constructed in many different ways to suit the needs of various applications. For example, the bottom stack may be made of building structural materials for architectural use or it may be made of automotive grade material for automotive use. For architectural use, a typical bottom stack is shown in the Figures comprising a substrate body (e.g. medium density fiberboard or MDF) and body-backing substrate (e.g. steel). Other non-limiting examples of substrate body components include high pressure laminate (HPL) or tricell may also be used in the construction of the bottom stack. Like the top stack, the bottom stack is also self-contained and can be handled by itself. The top stack may be fixed to the bottom stack using pressure sensitive adhesive (PSA), transfer tape or adhesive which is melted and solidified in place.

### Example: Prototypes of a Willow Glass Laminate Force Sensor

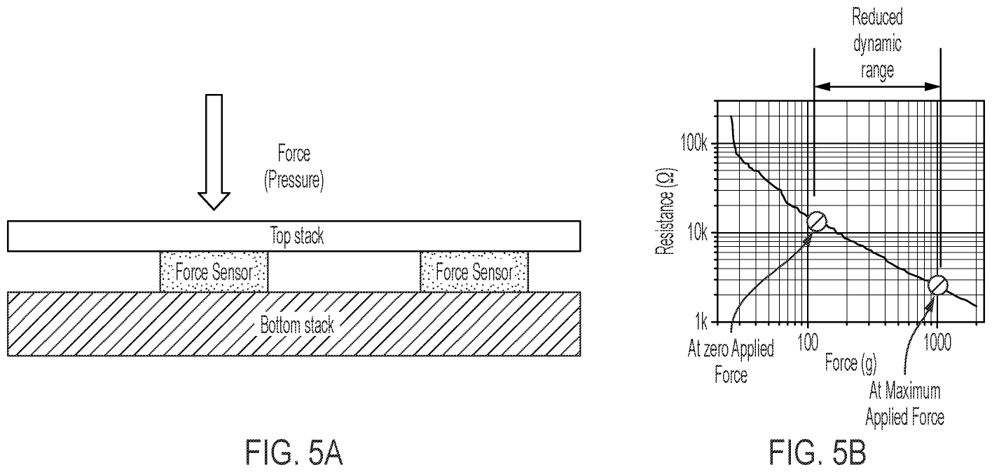

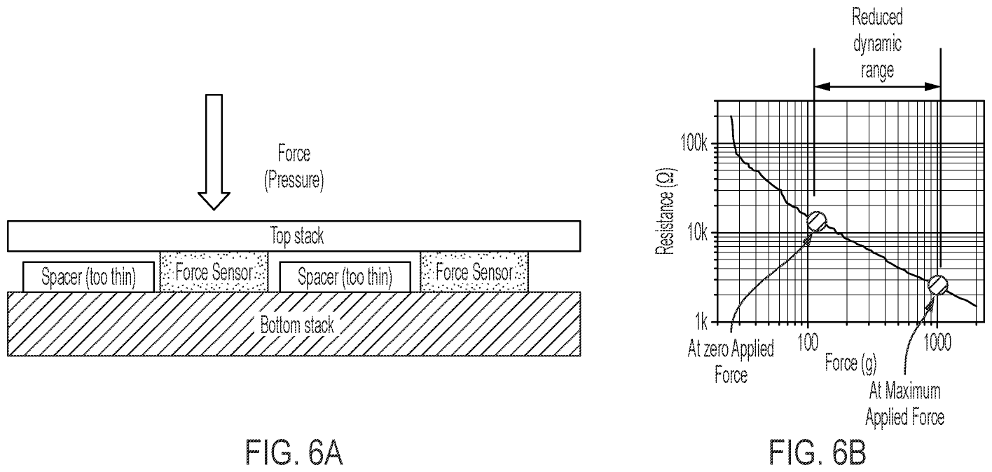

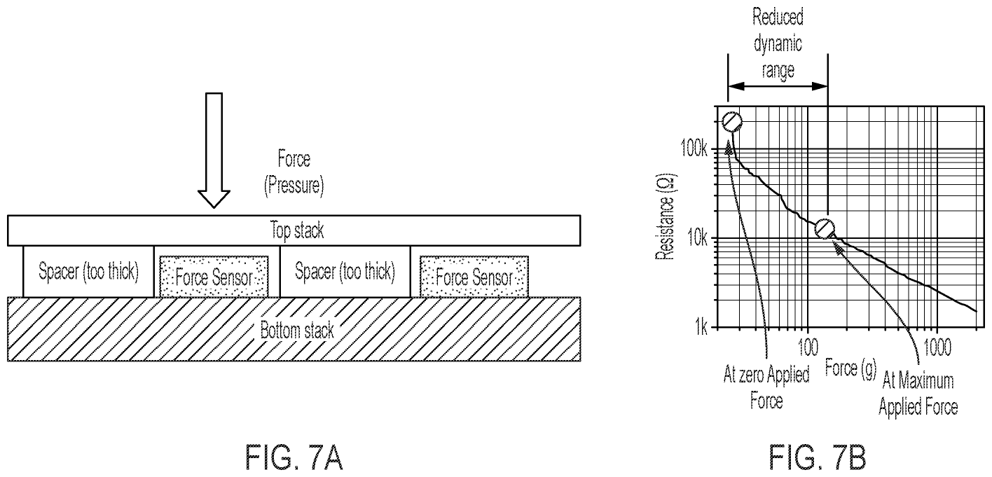

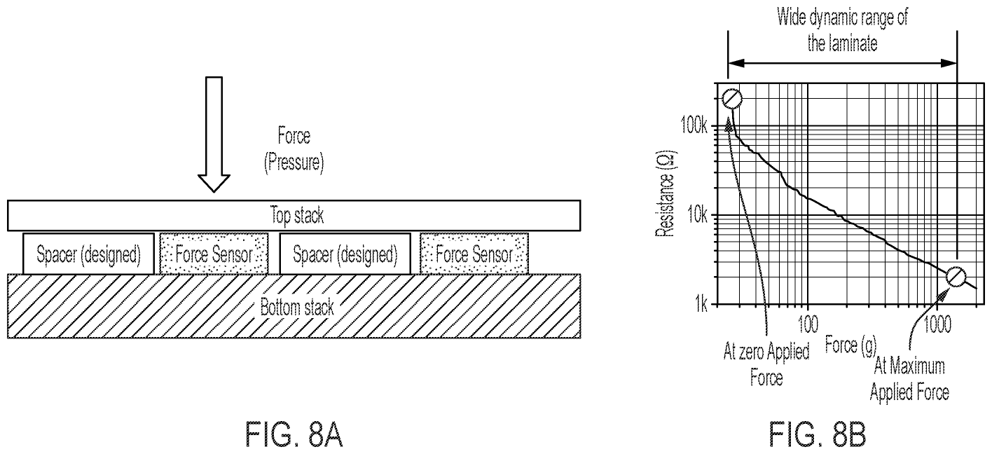

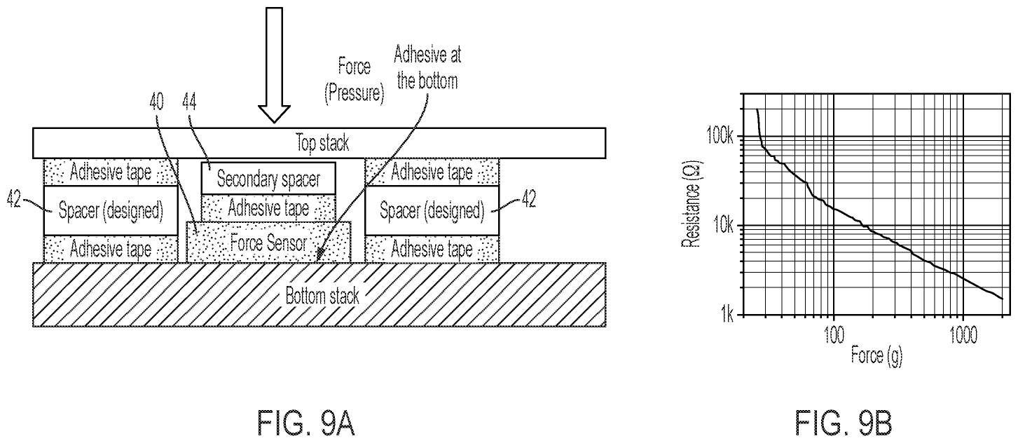

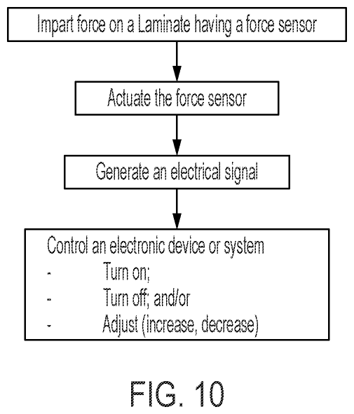

A series of glass laminate builds (prototypes) were completed with the force sensor positioned between the top stack and bottom stack, as shown in FIGS. 5A through 9B, in order to evaluate the resistance vs. force curves and understand the dynamic range of the laminate with various force sensor and spacer vs. no spacer configurations.

The build had constant top stack and bottom stack configurations. Willow glass was utilized as the uppermost, top layer of the top stack (e.g. actuating occurred on Willow surface). The top stack was made of Willow glass and steel. The bottom stack made with medium density fiberboard. The top stack was approximately 1.35 mm thick and the bottom part was approximately 13.5 mm thick. Both the top stack and the bottom stack were 300×300 mm in size. Two force sensors (force resisting sensors made by Interlink Electronics (FSR Model 406)) were utilized between the top stack and bottom stack.

Each force sensor was configured in electrical communication with a resistance-controlled LED output circuit that turned on a number of LEDS, depending on the applied voltage. While this circuit is designed for use in FSR force sensors, its utilization in a Willow laminate prototype showed that application of force on the top stack of the Willow laminate produces a corresponding effect (as compared to FSR force sensors) and a series of LEDs was actuated—turned on and off—by applying pressure with finger pressure on top of the Willow laminate (at the force sensor locations).

The FSR406 force sensor was 43.7 mm square with an active area 39.6 mm square. The sensor thickness was 0.46 mm. The sensor has an adhesive surface which was used to fix two sensors to the bottom stack at two locations.

Five glass laminates were constructed, with spacer configuration and corresponding measured dynamic ranges as set out below and in accompanying FIGS. 5A through 9B.
Build 1: The top stack and the bottom stack are fixed together with the force sensor in between without the use of any spacers. During manufacturing of the laminate, the components are adhered together and force is applied, which results in remaining strain which is built-in to the embedded force sensor. The built-in strain will reduce the resistance of the laminate, and the resulting dynamic range of the force sensor n the glass laminate.
Build 2: The top stack and the bottom stack are fixed together with the force sensor in between and with spacers positioned between the top stack and the bottom stack. With Build 2, the spacers are too thin (e.g. adjacent spacer thickness is less than the force sensor thickness), so the top stack impacts strain on the force sensor even without application of an external force (e.g. no actuating force), which reduces the resistance of the sensor (at zero applied force) and in turn reduces the dynamic range of the sensor.
Build 3: The top stack and the bottom stack are fixed together with the force sensor in between and with spacers positioned between the top stack and the bottom stack. With Build 3, the spacers are too thick (e.g. adjacent spacer thickness is greater than force sensor thickness), so a small actuating force will not actuate the force sensor. With Build 3, the threshold force to see any resistance change is significant, as it's necessary to deflect the top stack to make contact with the force sensor. In addition, the maximum force applied to the outer surface of the laminate may not be sufficient to bring the resistance to the force sensor (e.g. commonly force sensors are engaged/actuated when an equal amount of force is applied to the sensor at its surface). The dynamic range of Build 3 is reduced.

In both Build 2 and Build 3, if a circuit is made to control a device based on the applied force on the glass laminate, the operating point will be different from part to part and from location to location in the glass laminate (e.g. a single large panel with multiple sensors). If a large surface area glass laminate is used with multiple force sensors and if the spacing between the top stack and the bottom stack varies from point to point, then the force sensors will have different applied force vs signal output characteristic, which is not desirable. The part to part variation which will be present is also not desirable in a commercial product.
Build 4: The spacing between the top stack and the bottom stack is carefully controlled with tailored spacer placement such that there is no load (force, pressure) condition on the force sensor because the adjacent spacer thickness is slightly greater (<0.010″ typically) than the thickness of the force sensor. This configuration results in (a) residual spacing between the force sensor and the laminate surface (e.g. bottom of top stack) that touches the force sensor and (b) mitigation of residual strain in the force sensor from manufacturing the laminate (e.g. integrating and mounting of the stacks to form the laminate). With the configuration of Build 4, the laminate behaves essentially like the force sensor itself at zero applied force condition and the resistance level is very high (for a resistance-based force sensor). The gap between the force sensor and the internal surface it touches when force is applied is small enough (<0.010″) so that minimum deflection of the top stack is needed to see the change in resistance with applied force. Build 4 results in the reliable and reproducible operation of the glass laminate acting as force (pressure) sensors.

Also, depending on the rigidity and construction of the top stack, a much wider dynamic range can be achieved with a configuration corresponding to Build 4 than with Builds 1-3.
Build 5: The spacing between the top stack and the bottom stack is carefully controlled with tailored spacer placement, including both adjacent spacer and actuating spacer, such that there is no load (force, pressure) condition on the force sensor because the adjacent spacer thickness and actuating spacer (complementing with the force sensor thickness) are configured is slightly greater (<0.010″ typically) than the thickness of the force sensor. To complement the sensor thickness, an adjacent spacer (e.g. a 300×300 mm spacer made with PETG plastic) was chosen with a thickness of 0.508 mm (e.g. slightly thicker than the sensor thickness). The adjacent spacer was attached to the bottom and the top plate with 0.150 mm thick adhesive tape on each side. The adjacent spacer was cut with holes (e.g. laser cut) as to accommodate the two force sensors.

The height difference between the FSR406 sensor layer and the spacer layer is 0.348 mm. As a method of fine tuning the gap, an actuating spacer (e.g. secondary spacer of 0.25 mm thickness) was put on the force sensor surface with a 0.075 mm adhesive layer. This created a very small gap between the force sensor and the surface of the top stack. This gap was configured to maintain the force sensor in the relaxed state (at very high resistance level) when no force (no actuating event) was applied to the glass laminate.

Also, as the gap was very small, only a small amount of force in an actuating even was capable of deflecting the top stack to generate force on the force sensor (e.g. so that the resistance could go down to very low level, imparting a wide dynamic range on the laminate having a force sensor therein). Using finger pressure to apply force, the maximum resistance was more than measurable (>10 Mohm) and the minimum resistance was of the order of 300 ohm.

Many variations and modifications may be made to the above-described embodiments of the disclosure without departing substantially from the spirit and various principles of the disclosure. All such modifications and variations are intended to be included herein within the scope of this disclosure and protected by the following claims.

1. A glass laminate, comprising:
a top stack, the top stack configured from a glass layer and a backer substrate, wherein the glass layer is adhered to the backer substrate via an adhesive;
a. a bottom stack, the bottom stack configured from a body substrate and body-backer substrate, wherein the body-backer substrate is adhered onto the body substrate via an adhesive;
wherein the top stack is configured to the bottom stack with an adhesive positioned therebetween; and
b. a force sensor integrated into at least one of: the top stack and the bottom stack, wherein the force sensor is configured to electrically communicate with a device or system;
wherein the glass laminate is configured to actuate a force sensor with a pressure event on the glass layer.

2. The glass laminate of claim 1, further comprising: a plurality of spacers configured between the glass layer and the backer substrate, wherein the spacers are configured such that the at least one force sensor is in a non-actuating configuration.

3. The glass laminate of claim 1,
wherein the spacer comprises an actuating spacer.

4. The glass laminate of claim 1,
wherein the spacer comprises an adjacent spacer.

5. The glass laminate of claim 1,
wherein the glass backing substrate is a thin glass.

6. The glass laminate of claim 1, wherein the glass backing substrate has a thickness of not greater than 300 microns.

7. The glass laminate of claim 1, wherein the layers of the laminate are adhered together with adhesive selected from the group consisting of: optically clear adhesive, pressure sensitive adhesive, and transparent tape.

8. The glass laminate of claim 1, wherein the body substrate comprises: medium density fiberboard (MDF) or high-pressure laminate (HPL).

9. The glass laminate of claim 1, wherein the body backer substrate comprises a metal sheet.

10. The glass laminate of claim 1, wherein the force sensor is configured with a plurality of spacer members, wherein the spacer members are positioned: (1) between the upper surface of the force sensor and the lower surface of the adjacent layer; (2) between two adjacent, spaced layers of the laminate and an edge of the sensor; and combinations thereof.

11. The glass laminate of claim 1, wherein the spacer includes at least one adjacent spacer and at least one actuating spacer.

12. The glass laminate of claim 1, wherein the adjacent spacer is configured with a sensor hole, sufficiently sized such the force sensor and electrical wiring are retained therein.

13. The glass laminate of claim 1, wherein the force sensor is configured with electrical wiring, wherein via the electrical wiring, an actuation signal is communicated to a location external to the glass laminate.

14. The glass laminate of claim 1, wherein the electrical wiring is configured to communicate an actuation signal from the force sensor in the laminate to a device or system, external to the laminate.

15. The glass laminate of claim 1, wherein the electrical wiring is configured to communicate an actuation signal from the force sensor in the laminate to a device or system, positioned on an external surface of the laminate or an adjacent position to the laminate.

16. The glass laminate of claim 1, wherein the electrical wiring is directed from the force sensor to exit the laminate via the spacer hole.

17. The glass laminate of claim 1,
wherein the force sensor is housed in the backer-substrate in a substrate sensor hole.

18. The glass laminate of claim 1,
wherein the force sensor is thicker than the backer substrate, a combination of adjacent spacers and actuating spacers are utilized between the glass layer and the backing-substrate layer.

19. The glass laminate of claim 1, wherein the force sensor is thinner than the backer substrate, wherein an actuating spacer is utilized between the glass layer and the force sensor.

20. The glass laminate of claim 1, wherein the glass layer includes an inorganic glass.

21.-39. (canceled)
